(19) United States
(12) Patent Application Publication
(10) Pub. No.: US 2009/0166688 A1
(43) Pub. Date: Jul. 2, 2009

(54) IMAGE SENSOR AND METHOD FOR MANUFACTURING THE SAME

(76) Inventor: Keun-Hyuk Lim, Songpa-gu (KR)

Correspondence Address: SHERR & VAUGHN, PLLC, 620 HERNDON PARKWAY, SUITE 200, HERNDON, VA, 20170, US

(21) Appl. No.: 12/344,449

(22) Filed: Dec. 26, 2008

(30) Foreign Application Priority Data
Dec. 27, 2007 (KR) 10-2007-0139373

(51) Int. Cl. H01L 29/06; H01L 21/00; H01L 31/18

(52) U.S. Cl. 257/291; 438/98; 257/E21.002; 257/E29.255; 257/E29.003

(57) ABSTRACT

An image sensor includes an interlayer dielectric including metal lines disposed on a semiconductor substrate; first conductive regions formed on a crystalline semiconductor substrate which is bonded to the semiconductor substrate, and connected with the metal lines; second conductive regions formed between the respective first conductive regions; first conductive-type high-density dopant regions adjoining the first conductive regions, being formed on the crystalline semiconductor substrate; and second conductive-type high-density dopant regions adjoining the second conductive regions, being formed between the respective first conductive-type high-density dopant regions.

The present application claims priority under 35 U.S.C. 119 to Korean Patent Application No. 10-2007-0139373 (filed on Dec. 27, 2007), which is hereby incorporated by reference in its entirety.

### BACKGROUND

Generally, an image sensor refers to a device that converts an optical signal to an electric signal using photosensitivity of a semiconductor. Image sensors are typically classified as either a charge coupled device (CCD) or a complementary metal oxide semiconductor (CMOS) image sensor. A CMOS image sensor, comprising a photodiode and a MOS transistor in a unit pixel, detects electric signals of each unit pixel in sequence by a switching manner and thereby forms an image. In the CMOS image sensor there may be a photodiode region that receives optical signals and converts the optical signals to electric signals, and a transistor region that processes the electric signals. These two regions may be arranged in a horizontal structure.

According to a related horizontal CMOS image sensor, the photodiode and the transistor are arranged on a substrate horizontally and adjacently to each other. Therefore, an additional area for forming the photodiode is utilized. As a result, a fill factor area is reduced and it becomes more difficult to optimize resolution.

### SUMMARY

Embodiments relate to an image sensor that includes vertical integration of a transistor and a photodiode, and a method for manufacturing the same. Also, embodiments relate to an image sensor that maximizes both the resolution and the sensitivity, and a method for manufacturing the same. Embodiments relate to an image sensor which reduces, or prevents, defects in a photodiode while permitting a photodiode of a vertical structure, and a method for manufacturing the same.

Embodiments relate to an image sensor that includes: an interlayer dielectric including metal lines disposed on a semiconductor substrate, first conductive regions formed on a crystalline semiconductor substrate which is bonded to the semiconductor substrate, and connected with the metal lines, second conductive regions formed between the respective first conductive regions, first conductive-type high-density dopant regions adjoining the first conductive regions, being formed on the crystalline semiconductor substrate, and second conductive-type high-density dopant regions adjoining the second conductive regions, being formed between the respective first conductive-type high-density dopant regions.

Embodiments relate to a method for manufacturing an image sensor that includes: forming an interlayer dielectric including metal lines on a semiconductor substrate, forming first conductive regions on a crystalline semiconductor substrate, in connection with the metal lines, forming second conductive regions between the respective first conductive regions on the crystalline semiconductor substrate, forming first conductive-type high-density dopant regions on the crystalline semiconductor substrate, to adjoin the first conductive regions, forming second conductive-type high-density dopant regions between the respective first conductive-type high-density dopant regions, to adjoin the second conductive regions; and connecting the crystalline semiconductor substrate to the semiconductor substrate.

### DRAWINGS

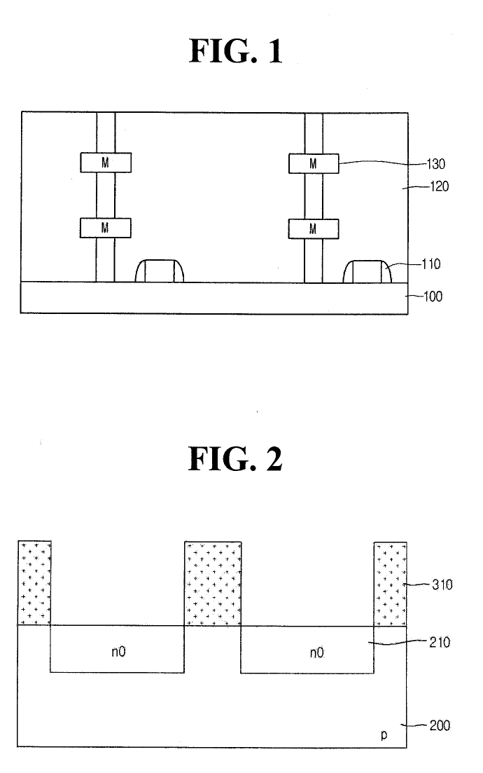

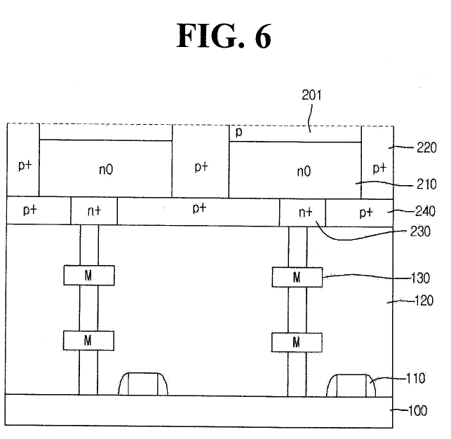

Example FIG. 1 to Example FIG. 6 are sectional views illustrating the processes of manufacturing an image sensor according to embodiments.

### DESCRIPTION

Example FIG. 6 is a sectional view of an image sensor according to embodiments. Referring to example FIG. 6, the image sensor comprises an interlayer dielectric 120 including metal lines (M) 130 disposed on, or over, a semiconductor substrate 100 including a circuit 110, first conductive-type dopant regions (n+) 230 disposed on, or over, the interlayer dielectric 120 to be connected to the metal lines 130, second conductive-type dopant regions (p+) 240 disposed between the first conductive-type dopant regions 230 to separate the first conductive-type dopant regions 230 from one another, photodiodes disposed on, or over, the first conductive-type dopant regions 230, and second conductive regions 220 disposed on, or over, the second conductive-type dopant regions 240 to separate the photodiodes from one another.

The semiconductor substrate 100 may be either a monocrystalline or polycrystalline silicon substrate, which may be applied with p-type or n-type dopants. On the substrate 100, the circuit 110 for each unit pixel may include, for example, any one of 3Tr, 4Tr and 5Tr structures according to the number of transistors. The metal line 130 formed in the interlayer dielectric 120 may include a plug. Being disposed corresponding to each unit pixel, the metal line 130 enables transmission of photoelectrons from the photodiode to the circuit.

The photodiode may include a first conductive region (n0) 210 disposed on, or over, the first conductive-type dopant region 230 and a crystalline semiconductor pattern 201 disposed between the first conductive regions 210. For example, the first conductive region 210 may comprise n-type dopants and the crystalline semiconductor pattern 201 may comprise p-type dopants.

The first conductive-type dopant region 230 connected with the metal line 130 may include high-density n-type dopants to serve as an ohmic contact of the photodiode. The second conductive-type dopant region 240 disposed between the first conductive-type dopant regions 230 may include high-density p-type dopants and separates the photodiode by the unit pixel. In other words, because the first conductive region 210 of the photodiode is in connection with the first conductive-type dopant region 230 formed for each unit pixel, and the first conductive-type dopant region 230 is in connection with the metal line 130, the photoelectrons generated from the photodiode can be transmitted to the circuit through the first conductive-type dopant region 230 and the metal line 130. Because the second conductive-type dopant region 240 may be disposed between the first conductive-type dopant regions 230, the first conductive regions 210 can be separated by the unit pixel.

As shown in example FIG. 6, the second conductive region 220, may be disposed on, or over, the second conductive-type dopant region 240 and formed of high-density p-type dopants to separate the photodiode by the unit pixel. When the second conductive region 220 is disposed between the photodiodes, it may also separate the photodiodes by the unit pixel along with the second conductive-type dopant region 240.

According to the embodiments, the photodiode may be formed on the semiconductor substrate 100 including the metal line 130 and accordingly, a vertical integration image sensor can be accomplished. Furthermore, the photodiode and the first conductive-type dopant region 230 connected with the photodiode may be separated by the unit pixel respectively by the second conductive region 220 and the second conductive-type dopant region 240. Therefore, crosstalk and noises can be reduced or prevented, consequently improving the optical sensitivity of the image sensor.

Referring to example FIG. 1, the interlayer dielectric 120 and the metal line 130 may be formed on, or over, the semiconductor substrate 100. The metal line 130 and the interlayer dielectric 120 may be deposited in a multilayer structure. The semiconductor substrate 100 may be, for example, a monocrystalline silicon substrate and may also be applied with p-type or n-type dopants.

The semiconductor substrate 100 may further include a device isolation layer that defines an active area and a field area thereon. On, or over, the active area, a transistor structure may be formed for each unit pixel, comprising a transfer transistor, a reset transistor, a drive transistor and a select transistor to convert received optical signals to electric signals in connection with the photodiode. The transistor structure may have any one of 3Tr, 4Tr and 5Tr structures.

The metal line 130 formed on, or over, the substrate 100 may be provided for each unit pixel and connects the photodiode with the circuit. Therefore, the metal line 130 is capable of transmitting the photoelectrons of the photodiode. The metal line 130 may include the metal line M and the plug, being formed of various conductive materials such as metal, alloy or silicide. For example, the metal line 130 may comprise aluminum, copper, cobalt, or tungsten. According to embodiments, the plug of the metal line 130 may be exposed to a surface of the interlayer dielectric 120.

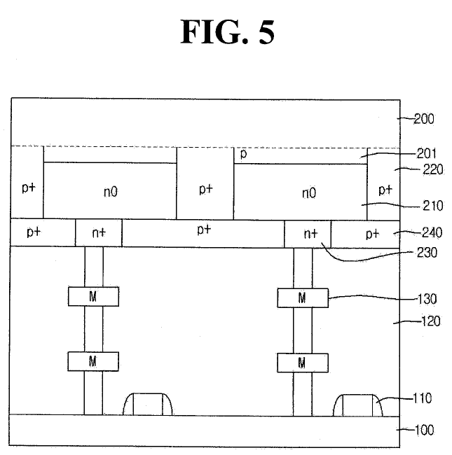

As shown in example FIG. 5, a crystalline semiconductor substrate 200 including a photodiode may be formed on the semiconductor substrate 100 including the metal line 130 and the interlayer dielectric layer 120. The photodiode may be formed on the crystalline semiconductor substrate 200 as shown in example FIG. 2.

The crystalline semiconductor substrate 200 may have a monocrystalline or polycrystalline structure and may be applied with p-type or n-type dopants. In FIG. 2, for example, a p-type substrate is used for the crystalline semiconductor substrate 200. The photodiode may include the first conductive region 210 and the crystalline semiconductor substrate 200 formed over the first conductive region 210. More specifically, the first conductive region (n0) 210 may include, for example, n-type dopants and the crystalline semiconductor substrate 200 may include, for example, p-type dopants.

As shown in example FIG. 2, the first conductive region 210 can be formed by forming a first photoresist pattern 310 on, or over, the crystalline semiconductor substrate 200 and then implanting the n-type dopants. For example, the first photoresist pattern 310 may be formed such that a surface of the crystalline semiconductor substrate 200 corresponding to the metal line 130 of the semiconductor substrate 100 is exposed. Thus, the first conductive region 210 is formed on, or over, the crystalline semiconductor substrate 200.

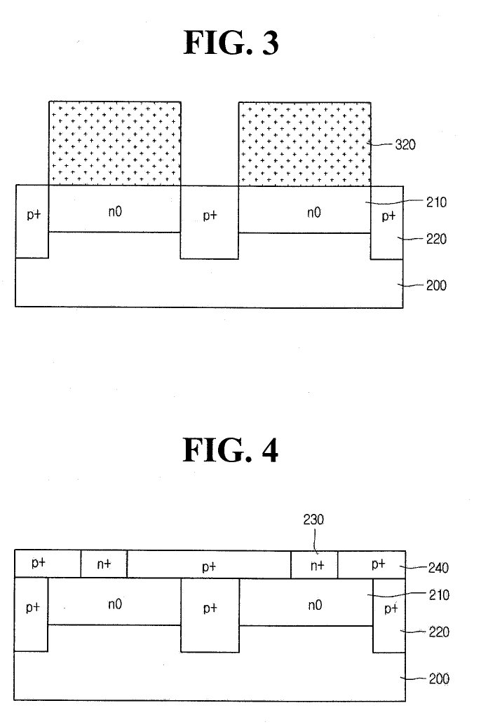

As shown in example FIG. 3, the second conductive region 220 that separates the photodiode by the unit pixel may be formed on, or over, the crystalline semiconductor substrate 200. The second conductive region 220 may be formed by forming a second photoresist pattern 320 on, or over, the crystalline semiconductor substrate 200 and then implanting high-density p-type dopants. Here, the second conductive region 220 may be formed so that the crystalline semiconductor substrate 200 is exposed except the first conductive region 210.

Therefore, since the second conductive region 220 may be formed between the first conductive regions 210 of the crystalline semiconductor substrate 200, the photodiode can be separated by the unit pixel. In other words, since the second conductive region 220 may be formed selectively on the crystalline semiconductor substrate 200 including the first conductive region 210, the photodiode which is formed by connection between the first conductive region 210 and the p-type crystalline semiconductor substrate 200 can be separated by the unit pixel.

According to embodiments, the first conductive region 210 may occupy a greater area than the second conductive region 220 so that a depletion region may be expanded, thereby increasing the generated photoelectrons. Although the second conductive region 220 may be formed after the first conductive region 210, the formation order can be switched as well.

As shown in example FIG. 4, the first conductive-type dopant region 230 and the second conductive-type dopant region 240 may be formed on, or over, the surface of the photodiode. Specifically, the first conductive-type dopant region 230 may include high-density n-type dopants while the second conductive-type dopant region 240 may include high-density p-type dopants. The first conductive-type dopant region 230 may be formed adjoining the first conductive region 210, and may also be disposed corresponding to the metal line 130 of the semiconductor substrate 100. If connected with the metal line 130 during postprocessing, the first conductive-type dopant region 230 may function as an ohmic contact that reduces a contact resistance.

The second conductive-type dopant region 240 may be disposed between the first conductive-type dopant regions 230, thereby separating the first conductive-type dopant regions 230 by the unit pixel. In other words, the second conductive-type dopant region 240 may perform the function of device isolation. In addition, whereas the first conductive-type dopant region 230 may be formed only on the first conductive region 210, the second conductive-type dopant region 240 can be formed to at least partly cover both the first and second conductive regions 210 and 220. Furthermore, as shown in example FIG. 3, the second conductive region 220 may be formed deeper than the first conductive region 210.

Referring to example FIG. 5, the semiconductor substrate 100 which includes the metal line 130 and the crystalline semiconductor substrate 200 which includes the photodiode may be connected to each other. The substrates 100 and 200 may be connected, for example, by a bonding process. In particular, the substrates 100 and 200 may be bonded so that the first conductive-type dopant region 230 is aligned with the metal line 130 of the semiconductor substrate 100. As a result, the crystalline semiconductor substrate 200 can be connected to an upper part of the semiconductor substrate 100. Thus, the semiconductor substrate 100 and the photodiode may be vertically integrated, thereby improving the fill factor.

Furthermore, the metal line 130 and the first conductive-type dopant region 230 can be interconnected in each unit pixel. Also, the second conductive-type dopant regions 240 may be disposed at both sides of the first conductive-type dopant region 230 and therefore the photodiode can be separated by the unit pixel. Accordingly, the photoelectrons generated from the photodiode can be transmitted to the metal line 130 through the first conductive-type dopant region 230 formed for each unit pixel.

Also, because the second conductive-type dopant region 240 may be formed at a lower part of the photodiode, defects occurring at a bonding surface with the semiconductor substrate 100 are reduced, thereby minimizing a dark current. More specifically, the defects that may be generated at the bonding surface between the semiconductor substrate 100 and the crystalline semiconductor substrate 200 may be combined with the p-type dopants. Therefore, electrons from the defects may be reduced or removed and, accordingly, the dark current can be minimized.

In addition, since the photodiode may be separated by the unit pixel, crosstalk and other noises can be prevented. Moreover, by omitting a dedicated device isolation process for the photodiode, the dark defect that may occur during trench etching can be prevented, and the manufacturing process can be simplified.

Referring to example FIG. 6, the crystalline semiconductor substrate 200 may be removed so that the photodiode remains on the semiconductor substrate 100. In other words, the crystalline semiconductor substrate 200 can be removed so that the first conductive region 210 and the crystalline semiconductor pattern 201 constituting the photodiode remain on the semiconductor substrate 100. After the crystalline semiconductor substrate 200 at the upper part of the photodiode is removed, the first and second conductive-type dopant regions 230 and 240, the second conductive region 220, and the photodiode are left on, or over, the semiconductor substrate 100. For example, the crystalline semiconductor substrate 200 may be removed by cutting or chemical mechanical polishing (CMP).

As shown in example FIGS. 5 and 6, removal of the crystalline semiconductor substrate 200 can be performed on the basis of the depth of the second conductive region 220. Because the second conductive region 220 may have a greater depth than the first conductive region 210, when the crystalline semiconductor substrate 200 is removed based on the second conductive region 220, the crystalline semiconductor pattern 201 remains on, or over, the first conductive region 210. A passivation layer, a color filter and a microlens may also be formed on the photodiode.

According to embodiments a photodiode may be formed on the semiconductor substrate including the metal line that includes a vertical integration structure. Because the photodiode may be formed on the upper part of the semiconductor substrate, the focal distance may be minimized and thereby the fill factor can be maximized. Also, on-chip circuitry may be additionally integrated that can enhance the performance of the image sensor as well as enabling reduction of the device size and the manufacturing cost.

According to embodiments, because a photodiode may be formed by implanting ions in a monocrystalline substrate, defects in the photodiode can be minimized. Also, because the first conductive-type dopant region may be formed at a lower part of the photodiode, a contact resistance between the photodiode and the semiconductor substrate can be minimized as well.

Additionally, the second conductive-type dopant region may be formed at both sides of the first conductive-type dopant region and, thus, perform a device isolation function. Therefore, generation of the crosstalk and the noises can be minimized. Furthermore, as the photodiode and the semiconductor substrate are connected, the second conductive-type dopant region may remove the electrons generated from the defects of the bonding surface. As a consequence, the dark current can be minimized.

According to embodiments, an image sensor may be achieved which includes a vertical integration structure of a transistor circuit and a photodiode. The vertical integration of the transistor circuit and the photodiode improves a fill factor and consequently, sensitivity can be maximized per pixel size. In addition, the processing cost for achieving the resolution can be minimized and because on-chip circuitry may be additionally provided, the performance of the image sensor can be maximized while reducing the device size and the manufacturing cost.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. An image sensor comprising:
an interlayer dielectric including electrically conductive lines disposed over a semiconductor substrate;
first conductive regions formed over a crystalline semiconductor substrate which is bonded to the semiconductor substrate, and coupled with the electrically conductive lines;
second conductive regions formed between the respective first conductive regions;
first conductive-type high-density dopant regions adjoining the first conductive regions, being formed over the crystalline semiconductor substrate; and
second conductive-type high-density dopant regions adjoining the second conductive regions, being formed between respective first conductive-type high-density dopant regions.

2. The image sensor according to claim 1, wherein the electrically conductive lines are arranged for each unit pixel.

3. The image sensor according to claim 1, wherein the first conductive regions comprise n-type dopants and the second conductive regions comprise p-type dopants.

4. The image sensor according to claim 1, wherein the first conductive-type high-density dopant regions comprise n-type dopants and the second conductive-type high-density dopant regions comprise p-type dopants.

5. The image sensor according to claim 1, wherein the electrically conductive lines are one of a metal, an alloy, and a silicide.

6. The image sensor according to claim 1, wherein the electrically conductive lines are one of copper, aluminum, cobalt, and tungsten.

7. A method for manufacturing an image sensor, comprising:
forming an interlayer dielectric including electrically conductive lines over a semiconductor substrate;
forming first conductive regions over a crystalline semiconductor substrate, coupled with the electrically conductive lines;
forming second conductive regions between the respective first conductive regions over the crystalline semiconductor substrate;
forming first conductive-type high-density dopant regions over the crystalline semiconductor substrate, to adjoin the first conductive regions;
forming second conductive-type high-density dopant regions between respective first conductive-type high-density dopant regions, to adjoin the second conductive regions; and
connecting the crystalline semiconductor substrate to the semiconductor substrate.

8. The method according to claim 7, wherein the electrically conductive lines are arranged for each unit pixel.

9. The method according to claim 7, wherein forming the first conductive regions, comprises:
forming a first photoresist pattern over the crystalline semiconductor substrate;
implanting dopant ions in at least a portion of the crystalline semiconductor substrate; and
removing the first photoresist pattern.

10. The method according to claim 9, wherein the first photoresist pattern is formed so that a surface of the crystalline semiconductor substrate corresponding to the electrically conductive lines is exposed.

11. The method according to claim 7, wherein forming the second conductive regions, comprises:
forming a first photoresist pattern that exposes the crystalline semiconductor substrate except the first conductive regions;
implanting dopant ions in the crystalline semiconductor substrate; and
removing the first photoresist pattern.

12. The method according to claim 11, comprising:
removing substantially all of the crystalline semiconductor substrate except for a photodiode structure.

13. The method according to claim 12, wherein when removing substantially all of the crystalline semiconductor substrate, a depth of removal is based on the depth of the second conductive regions.

14. The method according to claim 12, wherein removing substantially all of the crystalline semiconductor substrate comprises cutting.

15. The method according to claim 12, wherein removing substantially all of the crystalline semiconductor substrate comprises a chemical-mechanical polishing process.

16. The method according to claim 7, wherein the first conductive-type high-density dopant regions are formed only on the first conductive regions.

17. The method according to claim 7, wherein the second conductive-type dopant regions are formed where both the first and second conductive regions adjoin.

18. The method according to claim 7, wherein the second conductive regions are formed deeper than the first conductive regions.

19. The method according to claim 7, wherein the semiconductor substrate and the crystalline semiconductor substrate are connected by a bonding process.

20. The method according to claim 7, wherein the electrically conductive lines are one of a metal, and alloy, and a silicide.
